(19) United States
(12) Patent Application Publication
(10) Pub. No.: US 2015/0187714 A1
(43) Pub. Date: Jul. 2, 2015

(54) INTEGRATED CIRCUITS INCLUDING COPPER PILLAR STRUCTURES AND METHODS FOR FABRICATING THE SAME

(71) Applicant: GLOBAL FOUNDRIES Singapore Pte. Ltd., Singapore (SG)

(72) Inventors: Mahesh Anant Bhatkar, Mumbai (IN); Tan Juan Boon, Singapore (SG); Liu Wei, Singapore (SG); Oswald Jens, Dresden (DE)

(73) Assignee: GLOBALFOUNDRIES Singapore Pte. Ltd., Singapore (SG)

(21) Appl. No.: 14/140,796

(22) Filed: Dec. 26, 2013

(51) Int. Cl. H01L 23/00

(52) U.S. Cl. CPC H01L 24/13; H01L 24/11; H01L 2224/10125; H01L 2224/13147; H01L 2224/13023; H01L 2924/14; H01L 2924/384; H01L 2924/2064; H01L 2224/11462

(57) ABSTRACT

Integrated circuits including copper pillar structures and methods for fabricating the same are disclosed. In one exemplary embodiment, an integrated circuit includes a last metal layer and a passivation layer disposed over the last metal layer, both the last metal and passivation layers being disposed over an integrated circuit active device on a semiconductor substrate. The integrated circuit further includes a copper pillar structure disposed partially within a first portion of the passivation layer and immediately over the last metal layer. The first portion of the passivation layer is defined by first and second sidewalls of the passivation layer and an upper surface of the last metal layer. The copper pillar structure includes a liner formed along the first and second sidewalls and over the upper surface of the last metal and a copper material within the liner. The copper pillar structure, including both the liner and the copper material within the liner, further extends to a height above an upper surface of the passivation layer.

### TECHNICAL FIELD

The present disclosure generally relates to integrated circuits and methods for fabricating integrated circuits. More particularly, the present disclosure relates to integrated circuits including copper pillar structures and methods for fabricating the same.

### BACKGROUND

The majority of present day integrated circuits are implemented by using a plurality of interconnected field effect transistors (FETs), also called metal oxide semiconductor field effect transistors (MOSFETs), or simply MOS transistors. A MOS transistor includes a gate electrode as a control electrode and spaced apart source and drain regions between which a current can flow. A control voltage applied to the gate electrode controls the flow of current through a channel between the source and drain regions.

Modern integrated circuits are made up of literally millions of active devices, such as transistors, capacitors, and the like. These devices are initially isolated from each other, but are later interconnected together to form functional circuits. Typical interconnect structures include lateral interconnections, such as metal lines (wirings), and vertical interconnections, such as vias and contacts. Interconnections are increasingly determining the limits of performance and the density of modern integrated circuits. On top of the interconnect structures, bond pads are formed and exposed on the surface of the respective semiconductor wafer or “chip.” Electrical connections are made through bond pads to connect the chip to a package substrate or another die. Bond pads can be used for wire bonding or so-called “flip-chip” bonding. As known in the art, a flip chip, also known as a controlled collapse chip connection or its acronym, C4, is a method for interconnecting semiconductor devices, such as integrated circuit chips and micro-electromechanical systems (MEMS), to external circuitry with solder bumps that have been deposited onto the chip pads. The solder bumps are deposited on the chip pads on the top side of the wafer during the final wafer processing step. In order to mount the chip to external circuitry (e.g., a circuit board or another chip or wafer), it is “flipped” over so that its top side faces down, and aligned so that its pads align with matching pads on the external circuit, and then the solder is flowed to complete the interconnect. This is in contrast to wire bonding, in which the chip is mounted upright and wires are used to interconnect the chip pads to external circuitry.

Structurally, a solder bump actually contains the bump itself and a so-called under-bump-metallurgy (UBM) located between the bump and a pad. An UBM generally contains an adhesion layer, a barrier layer and a wetting layer, arranged in that order, on the pad. The bumps themselves, based on the material used, are classified as solder bumps, gold bumps, copper pillar bumps, and bumps with mixed metals. In copper pillar bump technology, instead of using a solder bump, the electronic component is connected to a substrate by means of a copper pillar bump (or more simply copper pillar), which achieves finer pitch with minimum probability of bump bridging, reduces the capacitance load for the circuits, and allows the electronic component to perform at higher frequencies.

In current practice, the integrated circuit is fabricated at a fabrication facility or “foundry” until the pad and required passivation layers (such as may be provided over the last metal layer). Thereafter, the integrated circuit is sent from the foundry to a outsourced semiconductor assembly and test (OSAT) facility, where the copper pillar is fabricated in electrical connection with the pad, and final connections to the external circuitry are made. Fabricating the copper pillar at an OSAT, however, has several drawbacks. For example, it is difficult for some OSAT facilities to fabricate copper pillars at the small pitches (such as about 10 microns or less) that are currently being developed and tested, whereas, at the foundry, the tooling is already well-enabled at such pitches. Further, OSAT facilities are unable to integrate the copper pillars with pillar strengthening structures, such as copper line via support structures, to enable a more robust connection between the integrated circuit and the external circuitry.

Accordingly, it is desirable to provide improved integrated circuit structures and methods for fabricating integrated circuits that include copper pillars for fabrication at a semiconductor foundry as opposed to an OSAT. It further is desirable to provide copper pillars in a configuration that is suitable to enable sub-10 micron pitch designs. Additionally, it is desirable to provide copper pillars connected with pillar strengthening structures. Furthermore, other desirable features and characteristics of the present disclosure will become apparent from the subsequent detailed description and the appended claims, taken in conjunction with the accompanying drawings and the foregoing technical field and background.

### BRIEF SUMMARY

Integrated circuits including copper pillar structures and methods for fabricating the same are disclosed. In one exemplary embodiment, an integrated circuit includes a last metal layer and a passivation layer disposed over the last metal layer, both the last metal and passivation layers being disposed over an integrated circuit active device on a semiconductor substrate. The integrated circuit further includes a copper pillar structure disposed partially within a first portion of the passivation layer and immediately over the last metal layer. The first portion of the passivation layer is defined by first and second sidewalls of the passivation layer and an upper surface of the last metal layer. The copper pillar structure includes a liner formed along the first and second sidewalls and over the upper surface of the last metal and a copper material within the liner. The copper pillar structure, including both the liner and the copper material within the liner, further extends to a height above an upper surface of the passivation layer.

In another exemplary embodiment, a method for fabricating an integrated circuit includes providing an integrated circuit including a last metal layer and a passivation layer disposed over the last metal layer, both the last metal and passivation layers being disposed over an integrated circuit devices formed over a semiconductor substrate and etching the passivation layer to form a first void region therein. Etching the passivation layer exposes a surface of the last metal layer disposed therebelow, the first void region being defined by sidewalls of the passivation layer and the exposed surface of the last metal layer. The method further includes forming a liner within the first void region and along the sidewalls thereof and over the exposed surface of the last metal layer thereof The second void region, smaller than the first void region, is defined by remaining portions of the first void region not filled by the liner. Still further, the method includes forming a copper pillar within the second void region and etching a first portion of the passivation layer surrounding the liner and the copper pillar to expose a portion of the liner. At least a second portion of the passivation layer remains disposed over the last metal layer and adjacent to the liner and the copper pillar.

### BRIEF DESCRIPTION OF THE DRAWINGS

The present disclosure will hereinafter be described in conjunction with the following drawing figures, wherein like numerals denote like elements, and wherein:

FIGS. 1-6 illustrate, in cross section, integrated circuit structures and methods for fabricating integrated circuits in accordance with various embodiments of the present disclosure; and

FIGS. 7A and 7B illustrate certain difference between an integrated circuit formed in accordance with embodiments of the present disclosure (FIG. 7B) and an integrated circuit formed in accordance with prior art techniques (FIG. 7A).

### DETAILED DESCRIPTION

The following detailed description is merely illustrative in nature and is not intended to limit the embodiments of the subject matter or the application and uses of such embodiments. Furthermore, there is no intention to be bound by any expressed or implied theory presented in the preceding technical field, background, brief summary or the following detailed description.

The present disclosure provides integrated circuits including copper (Cu) pillar structures and methods for fabricating the same. As employed throughout this disclosure, the term “Cu pillar” refers to a conductive pillar (a post or a standoff) formed of copper or copper alloys. The Cu pillar may be applied over a last metal layer (as used herein, the term “last metal layer” refers to the final metallization layer formed on an integrated circuit structure prior to connecting the integrated circuit structure with external circuitry) on a semiconductor chip for a flip chip assembly, or other similar applications. For the sake of brevity, conventional techniques related to integrated circuit device fabrication may not be described in detail herein. For example, the illustrated embodiments show the integrated circuits at a stage of fabrication wherein one or more circuit devices, such as transistors, resistors, and the like, have been previously formed using techniques know in the art. Moreover, the various tasks and process steps described herein may be incorporated into a more comprehensive procedure or process having additional steps or functionality not described in detail herein. In particular, various steps in the manufacture of semiconductor-based transistors are well-known and so, in the interest of brevity, many conventional steps will only be mentioned briefly herein or will be omitted entirely without providing the well-known process details.

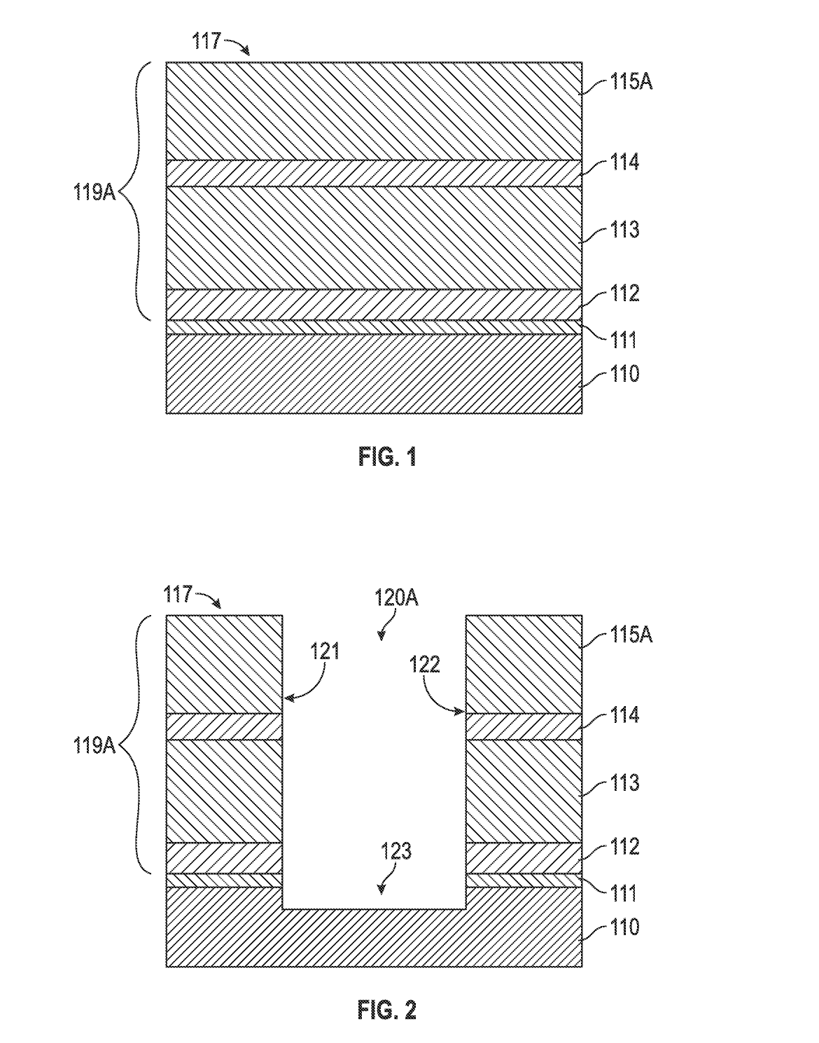

FIGS. 1-6 illustrate, in cross section, integrated circuit structures and methods for fabricating integrated circuits in accordance with various embodiments of the present disclosure. With reference now to FIG. 1, a passivation layer 119A disposed over a last metal layer 110 are provided over a non-illustrated semiconductor substrate. The semiconductor substrate is defined to mean any construction including semiconductor materials, including, but is not limited to, bulk silicon, a semiconductor wafer, a silicon-on-insulator (SOI) substrate, or a silicon germanium substrate. Other semiconductor materials including group III, group IV, and group V elements may also be used. The substrate may further include a plurality of isolation features (not shown), such as shallow trench isolation (STI) features or local oxidation of silicon (LOCOS) features. The isolation features may define and isolate the various microelectronic elements (not shown), also referred to herein as active integrated circuit structures. Examples of the various microelectronic elements that may be formed in the substrate include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.); resistors; diodes; capacitors; inductors; fuses; or other suitable elements. Various processes are performed to form the various microelectronic elements including deposition, etching, implantation, photolithography, annealing, or other suitable processes. The microelectronic elements are interconnected to form the integrated circuit device, such as a logic device, memory device (e.g., static random access memory or SRAM), radio frequency (RF) device, input/output (I/O) device, system-on-chip (SoC) device, combinations thereof, or other suitable types of devices.

The semiconductor substrate further includes disposed thereover non-illustrated inter-layer dielectric layers and a metallization structure overlying the active integrated circuit structures, of which last metal layer 110 forms a portion. The inter-layer dielectric layers in the metallization structure include low-k dielectric materials, un-doped silicate glass (USG), silicon nitride, silicon oxynitride, or other commonly used materials. The dielectric constants (k value) of the low-k dielectric materials may be less than about 3.9, or less than about 2.8. Metal lines in the metallization structure, such as last metal layer 110, may include copper or copper alloys. One skilled in the art will realize the formation details of the metallization structure.

As noted above, FIG. 1 also shows a passivation layer 119A formed overlying the semiconductor substrate and in particular overlying the last metal layer 110. Regarding the purpose and function of the passivation layer 119A, due to the current focus on increasing circuit density and speed, the use of copper as the interconnect material has grown significantly since copper exhibits lower resistivity and lower susceptibility to electromigration failure as compared to aluminum. Despite these advantages, one drawback of using copper is that it readily diffuses into the surrounding dielectric material during subsequent processing steps. To inhibit the diffusion of copper, copper interconnects are often capped with a protective barrier layer referred to as a passivation layer. The passivation layer 119A is formed of a non-organic material selected from un-doped silicate glass (USG), silicon nitride, silicon oxynitride, silicon oxide, or combinations thereof In some alternative embodiments, the passivation layer 119A is formed of a polymer layer, such as an epoxy, polyimide, benzocyclobutene (BCB), polybenzoxazole (PBO), or the like, although other relatively soft, often organic, dielectric materials can also be used.

In the embodiment illustrated in FIG. 1, passivation layer 119A for formed of five separate layers 111-115A. Layer 111 may be a silicon carbide-based passivation material layer including nitrogen. In one example, silicon carbide with nitrogen deposited using chemical vapor deposition (CVD) from a trimethylsilane source, which is commercially available from Applied Materials under the tradename of BLOK®, is used as the layer 119A and is the layer that is disposed over the copper last metal layer 110 formed by the damascene process. The compound with less nitrogen (N) (less than about 5 mol %), i.e., SiₐC_{b}N_{c}H_{d}, is referred to as “BLOK”, and the compound with more N (about 10 mol % to about 25 mol %), i.e., Si_{w}CₓN_{y}H_{z}, is referred to as “NBLOK”. BLOK has a lower dielectric constant of less than 4.0, whereas NBLOK has a dielectric constant of about 5.0. While BLOK is not a good oxygen barrier but is a good copper (Cu) barrier, NBLOK is both a good oxygen barrier and a good Cu barrier. In an exemplary embodiment, the layer 111 includes an NBLOK material.

Layers 112-115A may thereafter alternate between silicon nitride and silicon oxide to form the completed passivation layer 119A. For example, as shown in FIG. 1, layer 112 may be a silicon nitride layer, layer 113 may be a silicon oxide layer, layer 114 may be another silicon nitride layer, and layer 115A may be another silicon oxide layer. Of course, the layers may be provided in different orders, or different numbers of layers may be provided, all within the scope of the present disclosure. A thickness of passivation layer 119A, as defined from its border with last metal layer 110 to an upper surface thereof, may be from about 1 micron to about 10 microns, for example from about 3 microns to about 8 microns, though the present disclosure is not intended to be limited by any passivation layer thickness.

With reference now to FIG. 2, the exemplary method continues by forming one or more layers of a masking material (not shown), such as a photoresist material, overlying the passivation layer 119A and forming an opening in the masking material that exposes a portion of the passivation layer. In accordance with one embodiment, the masking material is conformably deposited or otherwise applied overlying the passivation layer and patterned to using conventional photolithography process steps to form an etch mask that includes the opening. The masking material may include one or more layers of material. For example, in an alternative embodiment, the masking material is realized as a tri-layer mask that includes an antireflective silicon oxynitride layer underlying a hard mask material layer (e.g., a carbon hard mask or the like), with a photoresist material overlying the hard mask material layer. The fabrication process continues by removing a portion of the passivation layer underneath and corresponding with the opening to form a first void region 120A within the passivation layer 119A. Removing the portion of the passivation layer 119A to form the first void region 120A may be accomplished using a suitable etching technique, such as a plasma-based RIE using an anisotropic etchant with an applied bias voltage to anisotropically etch the passivation layer 119A and expose an upper surface 123 of the underlying last metal layer 110. The first void region 120A thus formed is defined by sidewalls 121, 122 of the passivation layer 119A and the upper surface 123 of the last metal layer 110. The void region 120A may have a depth (defined from passivation layer upper surface 117 to last metal layer upper surface 123) that is substantially equal to the above-noted thickness of the passivation layer. The void region 120A may have a width (defined between sidewalls 121, 122) in a ratio of about 1:1 to about 1:2 with respect to the depth thereof However, it will be appreciated that the present disclosure is not intended to be limited by any particular dimensions of the void region 120A. Subsequent to etching, the masking material may be removed using techniques known in the art, leaving the structure substantially as illustrated in FIG. 2.

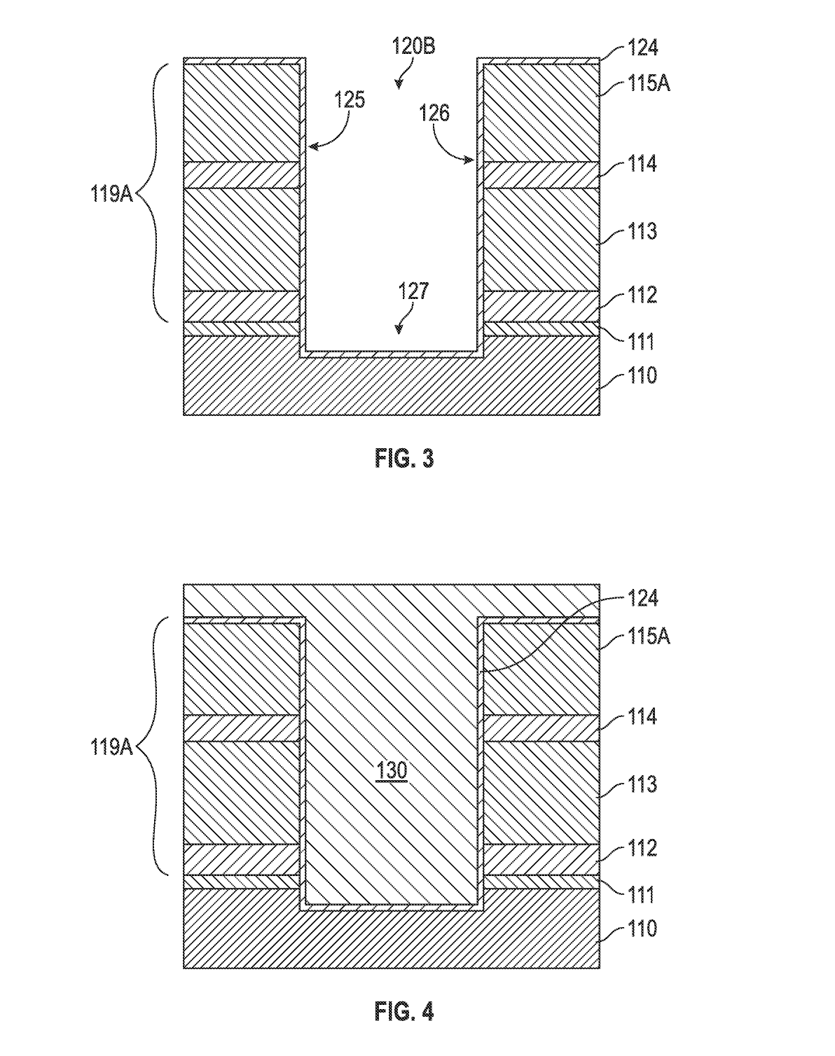

Referring now to FIG. 3, in accordance with one embodiment, a barrier material layer or “liner” 124 is formed by conformably depositing a layer of a material having barrier properties (with respect to the diffusion of copper), such as titanium nitride (TiN), tantalum nitride (TaN) (or possibly Ti or Ta metal), and other materials as will be known to those having ordinary skill in the art, using physical vapor deposition (PVD), sputtering, or the like. The liner 124 may have a thickness of about 1 nm to about 50 nm, although generally any suitable thickness may be used. The liner 124 is provided to prevent diffusion of the subsequently-formed copper pillar (see FIG. 4) into the surrounding passivation layer 119A. The liner is initially deposited over the entire substrate, however, a subsequent etching or polishing step may remove the liner 124 from over the upper surface 117 of the passivation layer 119A, leaving it only formed within the void 120A (see FIG. 4). With the liner 124 thus deposited, the void region 120A is slightly reduced in dimension, and is referred to in FIG. 3 as void region 120B. Void region 120B has sidewalls 125, 126 formed of the barrier liner material, and it has a lower surface 127 also formed of the barrier liner material.

Reference is now made to FIG. 4, which illustrates the formation of a copper pillar 130. (As used herein, the term “copper pillar” will refer only to the copper device 130 shown in FIG. 4 et seq., while the term “copper pillar structure” will refer to the copper pillar 130 in combination with the barrier liner 124. To form the copper pillar 130, a seed layer (not separately illustrated), which is formed of copper or copper alloys by physical vapor deposition (PVD) or sputtering, is formed to provide a starting layer over which the copper pillar 130 may be formed by using a subsequent electroplating process. The seed layer may be deposited to a thickness of about 500 to about 10,000 Angstrom, for example. After the seed layer is deposited, electro-chemical plating (ECP) is carried out to form the copper pillar 130. Alternatively, other deposition processes may be employed, such as electro-less plating, sputtering, CVD, and others. The copper pillar 130 is formed so as to completely fill the void 120B. In some embodiments, to ensure a complete fill, excess copper may be formed, such as over the upper surface 117 of the passivation layer 119A.

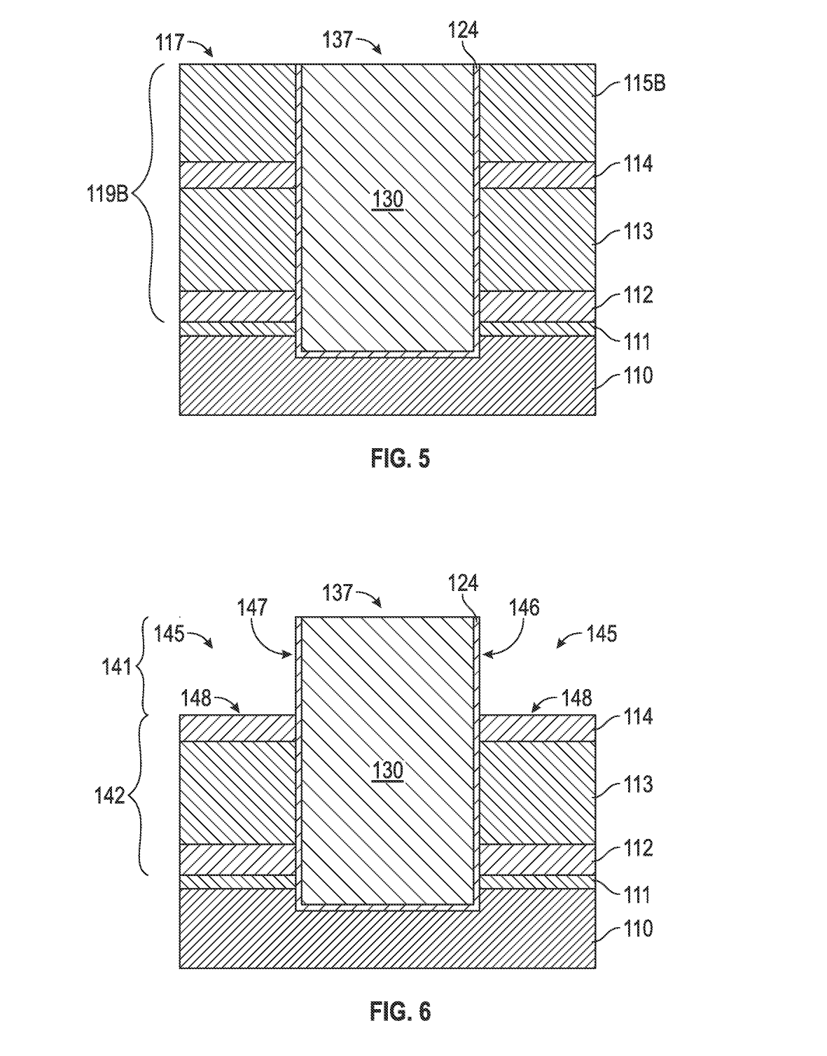

With reference now to FIG. 5, any excess copper that was plated in the formation of the copper pillar 130 may be removed using, for example, chemical mechanical planarization or polishing (CMP). The height of passivation layer 119B, and the pillar 130, is reduced somewhat due to the CMP process, as shown in FIG. 5. As known in the art, the CMP process uses an abrasive and corrosive chemical slurry in conjunction with a polishing pad and retaining ring, typically of a greater diameter than the wafer. The pad and wafer are pressed together by a dynamic polishing head and held in place by a plastic retaining ring. The dynamic polishing head is rotated with different axes of rotation (i.e., not concentric). Typical CMP tools include a rotating and extremely flat platen that is covered by a pad. The wafer that is being polished is mounted upside-down in a carrier/spindle on a backing film. The retaining ring keeps the wafer in the correct horizontal position. A slurry introduction mechanism deposits the slurry on the pad. Both the platen and the carrier are then rotated and the carrier is kept oscillating as well. A downward pressure/down force is applied to the carrier, pushing it against the pad. The down force applied depends on the contact area which, in turn, is dependent on the structures of both the wafer and the pad. The CMP process may be performed such that the copper is removed from everywhere except from within the void region 120B, thus leaving a copper pillar 130 that is substantially commensurate in size with the void region 120B. Thus, the copper pillar has an upper surface 137 that is coplanar with the upper surface 117 or the passivation layer 119B. Thereafter, the illustrate structure may be exposed to an appropriate anneal process to anneal the copper pillar 130. In the annealing process, the integrated circuit is exposed to an elevated temperature for any suitable annealing time. the present disclosure is not intended to be limited by any particular copper annealing conditions. After annealing, a structure substantially as shown in FIG. 5 is formed.

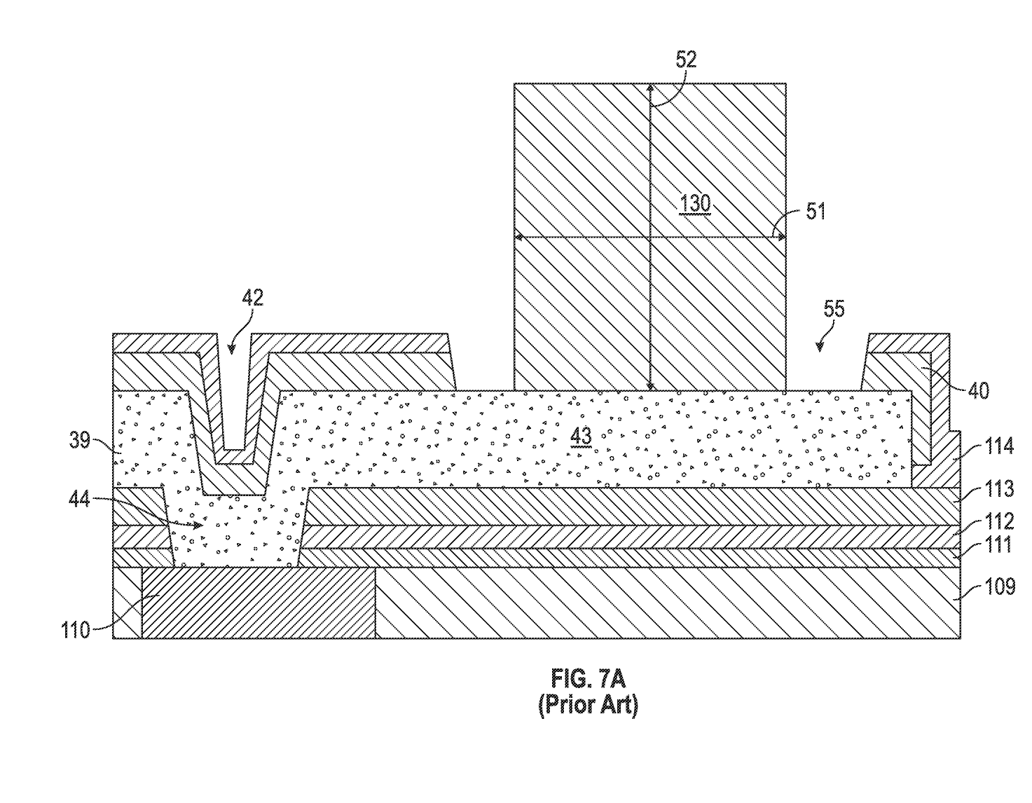

With reference now to FIG. 6, the exemplary method continues with an etching step that etches at least a portion 141 of the passivation layer 119B. As illustrated in FIG. 6, the portion 141 of the passivation layer that is etched includes the upper silicon oxide layer 115B. In this respect, a suitable etch may be employed, such as a blanket oxide dry (RIE) etch that does not require a masking layer (the etch chemistry being selective to oxide). After this etching process, silicon upper silicon nitride layer 114 becomes the upper layer of the passivation layer, having upper surface 148. As such, while a portion 141 of the passivation layer 119B is removed by the etching process, another portion of the passivation layer 142, including layers 111-114, remains substantially in place. The void space adjacent to the copper pillar structure (liner 124 and pillar 130) is shown in FIG. 6 as space 145. Thus, after the etching process, the copper pillar structure has exposed sidewalls 146, 147 formed by the barrier liner 124. The resulting structure, as shown in FIG. 6, has a first portion of the copper pillar structure being disposed within the remaining portion 142 of the passivation layer 119B, and a second portion of the copper pillar structure being disposed above the upper surface 148 of the remaining portion 142 of the passivation layer 119B. A ratio of the first portion to the second portion may be, for example, from about 0.5:1 to about 2:1, in some embodiments.

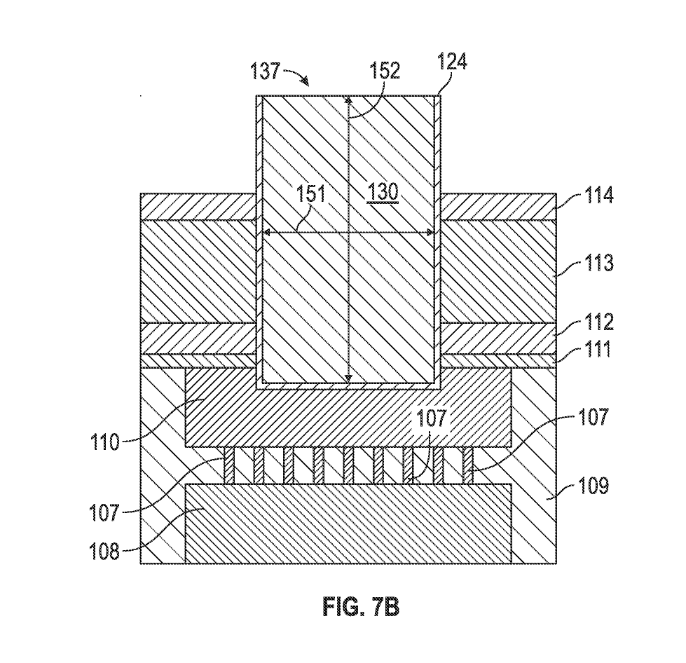

Accordingly, a method for fabricating an integrated circuit, the method being suitable for performance at a semiconductor foundry (as opposed at an OSAT), has been disclosed. FIGS. 7A and 7B illustrate certain difference between an integrated circuit formed in accordance with embodiments of the present disclosure (FIG. 7B) and an integrated circuit formed in accordance with prior art techniques (FIG. 7A). As described above, and as shown in FIG. 7B, the integrated circuit fabricated in accordance with embodiments of the present disclosure includes a last metal layer 110 and a passivation layer 142 disposed over the last metal layer 110, both the last metal and passivation layers 110, 142 being disposed over an integrated circuit active device on a semiconductor substrate having one or more insulation layers 109 (such as fluorinated TEOS) formed thereon. The integrated circuit further includes a copper pillar structure 124, 130 disposed partially within a first portion of the passivation layer 142 and immediately over the last metal layer 110. The first portion of the passivation layer is defined by first and second sidewalls of the passivation layer 121, 122 and an upper surface of the last metal layer 127. The copper pillar structure 124, 130 includes a liner 124 formed along the first and second sidewalls 121, 122 and over the upper surface of the last metal layer 127 and a copper material (or pillar) 130 formed within the liner 124. The copper pillar structure, including both the liner 124 and the copper material (or pillar) 130 within the liner 124, further extends to a height above an upper surface 148 of the passivation layer.

A further benefit of forming the copper pillar structure in accordance with the above-described embodiments at a foundry is that the copper pillar structure may be formed so as to be supported by an underlying support structure, such as a copper line via support (CLVS) structure 108, as shown in FIG. 7B. CLVS 108 includes a base metal layer 108 (formed of, for example, copper) with a plurality of support vias 107 connected between the base metal layer 108 and the last metal layer 110. With the copper pillar structure thus being connected with the last metal layer 110, additional structural support is provided thereto via the CLVS 108. This additional structural support is provided to reduce defects and to increase process robustness. Still further, the copper pillar structure shown in FIG. 7B is able to be fabricated at a pitch of at or less than about 10 microns, when fabricated at a foundry, thus enabling more integrated circuit features to be included on a smaller chip area.

The structure shown in FIG. 7B is in contrast to integrated circuits fabricated in accordance with prior art fabrication methods, such as shown in FIG. 7A. In prior art structures, the integrated circuit may include a pad layer 39 (such as an aluminum pad layer) connecting between the last metal layer 110 and the copper pillar 130. The pad layer 39 includes a pad portion 43 and a via portion 44 (see the “divot” in the passivation layers 40, 114 formed thereby). The passivation layers 111-114 (and additionally silicon oxide layer 40) are provided as described above. Further, if produced at an OSAT, the copper pillar 130 may not be able to be produced at smaller pitches, such as at or less than about 10 microns, for example.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

1. An integrated circuit comprising:
a last metal layer and a passivation layer disposed over the last metal layer, both the last metal and passivation layers being disposed over an integrated circuit active device on a semiconductor substrate, the last metal and passivation layers being in direct physical contact with one another;
a copper pillar structure disposed partially within a first portion of the passivation layer and immediately over and in direct physical contact with the last metal layer, wherein the first portion of the passivation layer is defined by first and second sidewalls of the passivation layer and an upper surface of the last metal layer, wherein the copper pillar structure has a width in a direction parallel to the upper surface of the last metal layer that is substantially invariant along a length of the copper pillar structure in a direction perpendicular to the upper surface of the last metal layer, and wherein the copper pillar structure comprises a liner formed along the first and second sidewalls and over the upper surface of the last metal and a copper material within the liner such that a distance between the first and second sidewalls in the direction parallel to the upper surface of the last metal layer defines the width of the copper pillar structure and such that the liner is in direct physical contact with the last metal layer,
wherein the copper pillar structure, including both the liner and the copper material within the liner, further extends to a height above an upper surface of the passivation layer.

2. The integrated circuit of claim 1, wherein the passivation layer comprises a multi-material passivation layer.

3. The integrated circuit of claim 2, wherein the passivation layer comprises a silicon carbide-based material layer, a first silicon nitride material layer, a silicon oxide material layer, and a second silicon nitride material layer.

4. The integrated circuit of claim 1, wherein the liner comprises a TiN material.

5. The integrated circuit of claim 1, wherein the copper pillar structure is formed at a pitch of about 10 microns or less.

6. The integrated circuit of claim 1, wherein the last metal layer comprises a copper material.

7. The integrated circuit of claim 1, further comprising a copper pillar support structure connected with the last metal layer.

8. The integrated circuit of claim 7, wherein the copper pillar support structure comprises a copper line via support structure comprises a plurality of via supports connected to the last metal layer and an underlying based metal layer.

9. The integrated circuit of claim 1, wherein the copper pillar structure has a height of about 1 micron to about 10 microns.

10. The integrated circuit of claim 1, wherein the copper pillar structure has a height of about 3 microns to about 8 microns.

11-19. (canceled)

20. The integrated circuit of claim 1, wherein the passivation layer comprises a lower surface, and wherein the copper pillar structure extends below the lower surface of the passivation layer across the entire width of the copper pillar structure.
